(19) United States
(12) Patent Application Publication
(10) Pub. No.: US 2026/0235711 A1
(43) Pub. Date: Aug. 13, 2026

(54) LIGHT GUIDE FOR SCANNING QUANTUM MATERIAL

(71) Applicant: Toyota Motor Engineering & Manufacturing North America, Inc., Plano, TX (US)

(72) Inventors: Paul D. SCHMALENBERG, Ann Arbor, MI (US); Ercan M. DEDE, Ann Arbor, MI (US)

(73) Assignees: Toyota Motor Engineering & Manufacturing North America, Inc., Plano, TX (US); Toyota Jidosha Kabushiki Kaisha, Toyota-Shi (JP)

(21) Appl. No.: 19/052,479

(22) Filed: Feb. 13, 2025

(51) Int. Cl. G01R 33/62; G01R 33/00; G01R 33/26; G01R 33/32

(52) U.S. Cl. CPC G01R 33/62; G01R 33/0094; G01R 33/26; G01R 33/323

(57) ABSTRACT

An aspect of the present disclosure is drawn to a sensor including: a light source configured to generate input light having an input wavelength λᵢ; an optical waveguide; an array of a plurality of quantum material chiplets; and an imaging array, wherein the optical waveguide is configured to transmit the input light to the array of the plurality of quantum material chiplets, wherein each quantum material chiplet is configured to absorb a portion of the input light from the optical waveguide and to emit a respective emission light having a respective emission wavelength λᵣₑ in response to the absorption of the portion of the input light and based on a respective parameter value at each quantum material chiplet, and wherein the imaging array is configured to detect each respective emission light and output a detection signal based on the respective parameter value at each quantum material chiplet.

### TECHNICAL FIELD

One or more embodiments relate generally optical detection of properties affecting quantum materials.

### BACKGROUND

Optically detected magnetic resonance (ODMR) is a double resonance technique by which the electron spin state of a crystal defect may be optically pumped for spin initialization and readout. ODMR has been shown in the laboratory setting to detect not only the presence of a magnetic field, but the magnitude and even the vector.

However, laboratory ODMR systems are too large, and not particularly mobile, for use outside the laboratory.

What is needed is an ODMR system that is compact and that can be easily transferred through commerce for use by an end user or end using system.

### SUMMARY

An aspect of the present disclosure is drawn to a sensor including: a light source configured to generate input light having an input wavelength λᵢ; an optical waveguide; an array of a plurality of quantum material (QM) chiplets; and an imaging array, wherein the optical waveguide is configured to transmit the input light to the array of the plurality of QM chiplets (QMCs), wherein each QM chiplet (QMC) is configured to absorb a portion of the input light from the optical waveguide and to emit a respective emission light having a respective emission wavelength λᵣₑ in response to the absorption of the portion of the input light and based on a respective parameter value at each QMC, and wherein the imaging array is configured to detect each respective emission light and output a detection signal based on the respective parameter value at each QMC.

In one or more embodiments of this aspect, the light source includes one of a group of light sources including a single tunable light source, an array of light emitting diodes, an array of vertical-cavity surface-emitting lasers, a grating antenna array operating over a frequency spectrum range, and combinations thereof.

In one or more embodiments of this aspect, the sensor further includes a microwave emitter configured to emit microwave pulses to the array of the plurality of QMCs and an optical modulating element configured to modulate the input light. In one or more of these embodiments, the optical waveguide includes an optical modulation portion that includes the optical modulating element, and the optical modulating element includes one of a group of optical modulating elements including a wavelength modulating element, a polarization modulating element, a mode modulating element, a nearfield phase modulating element, a gradient index lens, a diffractive element, a refractive element, a lenticular array, an intensity modulating element, and combinations thereof.

In one or more embodiments of this aspect, the light source, the optical waveguide, the array of the plurality of QMCs, and the imaging array are a unitary device.

In one or more embodiments of this aspect, the sensor further includes a baffle configured to reduce cross-talk between a first QMC of the array of the plurality of QMCs and a second QMC of the array of the plurality of QMCs.

In one or more embodiments of this aspect, each QMC is configured to emit the respective emission light having the respective emission wavelength λᵣₑ based on the respective parameter value that includes one value of a group of parameter values including a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each QMC.

Another aspect of the present disclosure is drawn to a system including: a controller; and a sensor, wherein the sensor includes: a light source configured to generate input light having an input wavelength λᵢ; an optical waveguide; an array of a plurality of QMCs; and an imaging array, wherein the optical waveguide is configured to transmit the input light to the array of the plurality of QMCs, wherein each QMC is configured to absorb a portion of the input light from the optical waveguide and to emit a respective emission light having a respective emission wavelength λᵣₑ in response to the absorption of the portion of the input light and based on a respective parameter value at each QMC, and wherein the imaging array is configured to detect each respective emission light and output a detection signal based on the respective parameter value at each QMC, and wherein the controller includes: a memory having instructions stored therein; and a processor configured to execute the instructions to cause the controller to: cause the light source to generate the input light; determine each respective parameter value at each QMC based on the detection signal.

In one or more embodiments of this aspect, the light source includes one of a group of light sources including a single tunable light source, an array of light emitting diodes, an array of vertical-cavity surface-emitting lasers, a grating antenna array operating over a frequency spectrum range, and combinations thereof.

In one or more embodiments of this aspect, the sensor further includes a microwave emitter configured to emit microwave pulses to the array of the plurality of QMCs, and an optical modulating element configured to modulate the input light. In one or more of these embodiments, the optical waveguide includes an optical modulation portion that includes the optical modulating element, and the optical modulating element includes one of a group of optical modulating elements including a wavelength modulating element, a polarization modulating element, a mode modulating element, a nearfield phase modulating element, a gradient index lens, a diffractive element, a refractive element, a lenticular array, an intensity modulating element, and combinations thereof.

In one or more embodiments of this aspect, the light source, the optical waveguide, the array of the plurality of QMCs, and the imaging array are a unitary device.

In one or more embodiments of this aspect, the sensor further includes a baffle configured to reduce cross-talk between a first QMC of the array of the plurality of QMCs and a second QMC of the array of the plurality of QMCs.

In one or more embodiments of this aspect, each QMC is configured to emit the respective emission light having the respective emission wavelength λᵣₑ based on the respective parameter value that includes one value of a group of parameter values including a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each QMC.

Another aspect of the present disclosure is drawn to method of detecting a field of parameter values. The method includes: causing, via a controller, a light source to generate input light having an input wavelength λᵢ, transmitting, via an optical waveguide, the input light to an array of a plurality of QMCs, each of the plurality of QMCs is configured to absorb a portion of the input light from the optical waveguide and to emit a respective emission light having a respective emission wavelength λᵣₑ in response to the absorption of the portion of the input light and based on a respective parameter value at each QMC; detecting, via an imaging array, each respective emission light; and outputting, via the imaging array, a detection signal based on the respective parameter value at each QMC to obtain the field of parameter values of the array of the plurality of QMCs.

In one or more embodiments of this aspect, the causing, via the controller, the light source to generate the input light includes causing, via the controller, one of a group of light sources including a single tunable light source, an array of light emitting diodes, an array of vertical-cavity surface-emitting lasers, a grating antenna array operating over a frequency spectrum range, and combinations thereof, to generate the input light.

In one or more embodiments of this aspect, the method further includes emitting, via a microwave emitter, microwave pulses to the array of the plurality of QMCs, and modulating, via an optical modulating element, the input light. In one or more of these embodiments, the optical waveguide includes an optical modulation portion that includes the optical modulating element, and the modulating, via the optical modulating element, the input light includes modulating via one of a group of optical modulating elements including a wavelength modulating element, a polarization modulating element, a mode modulating element, a nearfield phase modulating element, a gradient index lens, a diffractive element, a refractive element, a lenticular array, an intensity modulating element, and combinations thereof, the input light.

In one or more embodiments of this aspect, the causing, transmitting, detecting, and outputting includes causing the light source to generate the input light, transmitting the input light to the array of the plurality of QMCs, detecting each respective emission light, and outputting a detection signal via the light source, the optical waveguide, the array of the plurality of QMCs, and the imaging array as a unitary device.

In one or more embodiments of this aspect, the method further includes reducing cross-talk, via a baffle, between a first QMC of the array of the plurality of QMCs and another a second QMC of the array of the plurality of QMCs.

### BRIEF SUMMARY OF THE DRAWINGS

The accompanying drawings, which are incorporated in and form a part of the specification, illustrate and explain example embodiments. In the drawings:

FIG. 1 illustrates a portion of a diamond lattice having a nitrogen vacancy (NV) center;

FIG. 2 illustrates a system for detecting a magnetic field using a NV center diamond;

FIG. 3 illustrates a non-limiting example system for optically detecting a field of a parameter using a quantum material (QM) chiplet array in accordance with aspects of the present disclosure;

FIG. 4 illustrates an oblique view of modulation controlling plates of the system of FIG. 3 in accordance with aspects of the present disclosure;

FIG. 5 illustrates a non-limiting example of a controller of the system of FIG. 3;

FIG. 6 illustrates an oblique view of a non-limiting example of an optical detector of magnetic resonance (ODMR) sensor having a QMC array in accordance with aspects of the present disclosure;

FIG. 7 illustrates a cross-sectional view of example light beams emitted from a non-limiting example laser array of the system of FIG. 3;

FIG. 8A illustrates a cross-sectional view of example light beams emitted from a non-limiting example laser array of the system of FIG. 3, after having been spatially modulated in accordance with one or more embodiments;

FIG. 8B illustrates a cross-sectional view of example light beams emitted from a non-limiting example laser array of the system of FIG. 3, after having been spatially modulated in accordance with one or more other embodiments;

FIG. 9 illustrates a planar view of a non-limiting example QMC array of the system of FIG. 3;

FIG. 10A illustrates overlapping light beams on a single QMC in accordance with one or more embodiments;

FIG. 10B illustrates overlapping light beams on a single QMC so as to create an interference pattern in accordance with one or more embodiments;

FIG. 10C illustrates a single light beam overlapping multiple QMCs in accordance with one or more embodiments;

FIG. 11 illustrates a planar view of a non-limiting example imaging array in accordance with one or more embodiments;

FIG. 12A illustrates a single emission area overlapping a plurality of detecting cells of an imaging array in accordance with one or more embodiments;

FIG. 12B illustrates a plurality of emission areas overlapping a single detecting cell of an imaging array in accordance with one or more embodiments;

FIG. 13A illustrates a planar view of an array of vertical-cavity surface-emitting lasers in accordance with one or more embodiments at a time t₁;

FIG. 13B illustrates a planar view of the array of vertical-cavity surface-emitting lasers of FIG. 13A at a time t₂;

FIG. 13C illustrates a planar view of the array of vertical-cavity surface-emitting lasers of FIG. 13B at a time t₃;

FIG. 14A illustrates a cross-sectional view of example light beams emitted from a non-limiting example laser array of the system of FIGS. 13A-C, after having been spatially modulated in accordance with one or more embodiments at a time t₄;

FIG. 14B illustrates a cross-sectional view of example light beams emitted from a non-limiting example laser array of the system of FIGS. 13A-C, after having been spatially modulated in accordance with one or more embodiments at a time t₅;

FIG. 15 illustrates a front view of a non-limiting example of a horseshoe-shaped integrated optical sensor (IOS) in accordance with one or more embodiments;

FIG. 16 illustrates a front view of another non-limiting example of a horseshoe-shaped IOS in accordance with one or more embodiments;

FIG. 17 illustrates a front view of a non-limiting example of a 90°-angle-turn-shaped IOS in accordance with one or more embodiments;

FIG. 18 illustrates a front view of a non-limiting example of a dual-output-split-shaped IOS in accordance with one or more embodiments;

FIG. 19 illustrates a front view of a non-limiting example of a dual-output-T-shaped IOS in accordance with one or more embodiments;

FIG. 20 illustrates a system for use to detect magnetic fields within a brain of a person, in accordance with aspects of the present disclosure;

FIG. 21 illustrates a system for use to detect strain on the surface of an aircraft wing, in accordance with aspects of the present disclosure; and

FIG. 22 illustrates a system for use to detect magnetic fields on the surface of an integrated circuit (IC) chip, in accordance with aspects of the present disclosure.

### DETAILED DESCRIPTION

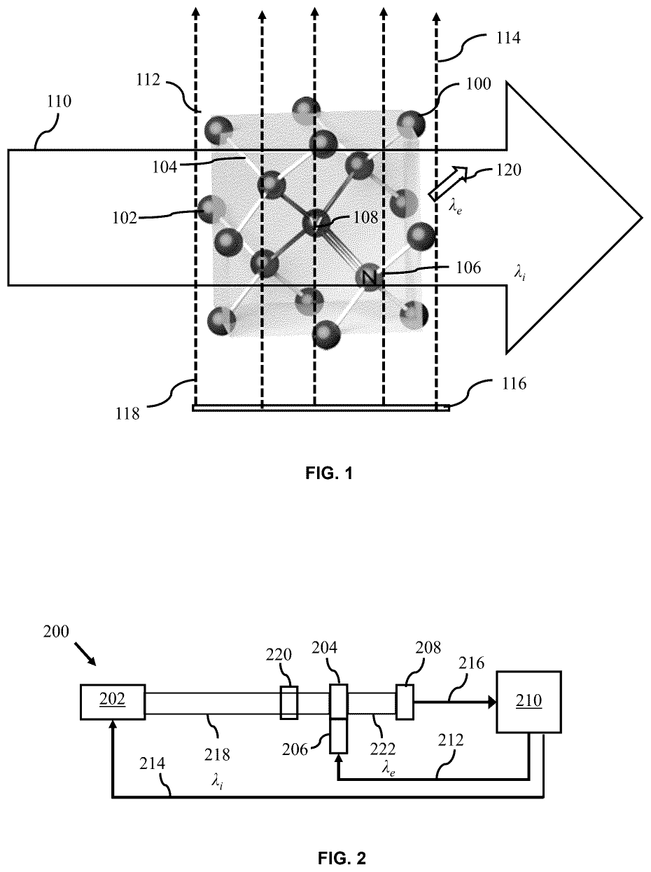

The basics of ODMR and an ODMR system will now be described with reference to FIGS. 1-2.

FIG. 1 illustrates a portion of a diamond lattice 100 having a nitrogen vacancy (NV) center.

As shown in the figure, diamond lattice 100 includes a plurality of carbon atoms, a sample of which is indicated as carbon atom 102. Each carbon atom has four covalent bonds with neighboring carbon atoms, a sample of which is indicated by covalent bond bar 104. A carbon atom is replaced by a nitrogen atom, for example nitrogen atom 106. Further a neighboring carbon atom is also removed, creating a vacancy 108. This combination of nitrogen atom 106 and vacancy 108 is called a NV center, which has many quantum properties. Diamond lattice 100 is irradiated with light 110 having an input wavelength λᵢ, wherein diamond lattice 100. Diamond lattice 100 is in the presence of a parameter 112, wherein parameter 112 affects electrons in the NV center. A magnetic field 114 is additionally near diamond lattice 100, wherein magnetic field 114 additionally affects electrons in the NV center. A microwave emitter 116 emits microwaves, indicated by dotted arrows 118 into diamond lattice 100. The NV center ultimately emits a photon 120 having an emission wavelength λₑ, wherein λᵢ≠λₑ, i.e., they are different colors.

An NV center may be created by several non-limiting methods, such as irradiating and annealing, chemical vapor deposition (CVD), ion implantation, and laser writing.

In irradiating and annealing, a diamond lattice (with just carbon atoms) is first irradiated with high energy particles (e.g., electrons, protons, neutrons). This creates lattice vacancies throughout the diamond. The diamond is then annealed at temperatures above 700° C. During annealing, the vacancies become mobile and are captured by existing nitrogen impurities in the lattice. For CVD, during CVD growth of diamond, a small fraction of nitrogen impurities can be incorporated. These nitrogen atoms can trap vacancies generated during the plasma synthesis process. For ion implantation, nitrogen ions can be directly implanted into specific locations in the diamond.

A usable quantum property of an NV center is the ability to optically detect a parameter near the NV center. For example, magnetic fields, electric fields, heat, stress, at or near the NV center will affect the states of electrons in the NV center. The affects on the states of electrons in the NV center may be detected optically, which may then be used to detect the amount, or even vector, of the effecting magnetic field, electric field, etc., that is at or near the NV center.

A system for exploiting the light emission by quantum material will now be described in greater detail with reference to FIG. 2.

FIG. 2 illustrates an ODMR system 200 for detecting a magnetic field using a NV center diamond 204.

As shown in the figure, ODMR system 200 includes a laser 202, a NV center diamond 204, a microwave emitter 206, a photodetector 208, a controller 210, a microwave emitter control line 212, a laser control line 214, and an output line 216.

In operation, controller instructs laser 202, via laser control line 214, to emit light 218 at an input wavelength λᵢ to NV center diamond 204. A parameter field 220 is at or near NV center diamond so as to affect NV center diamond. In this example, let parameter field 220 be a magnetic field. Controller instructs microwave emitter 206, via microwave emitter control line 212, to emit microwave pulses to NV center diamond 204. NV center diamond 204 will emit light 222 at an emitted wavelength λₑ. Photodetector 208 detects light 222 and outputs a detection signal to controller 210 via output line 216.

The magnetic field-induced splitting of the ms=±1 spin states of electrons in NV center diamond 204 can be measured by optically detecting with ODMR system 200. Microwave pulses from microwave emitter 206 drive transitions between the ground state spin states (ms=0 and ms=±1) of electrons in NV center diamond 204. Applying microwave pulses at the appropriate frequency (typically around 2.87 GHz), can enable coherently control of the spin state of electrons in NV center diamond 204. The frequency at which the microwave pulse from microwave emitter 206 induces spin transitions in electrons in NV center diamond 204 is sensitive to external magnetic fields due to the Zeeman effect. The precise frequency difference between the split ms=±1 states allows for quantitative measurement of the magnetic field strength and direction, making NV centers an excellent quantum sensor for magnetometry.

By measuring the exact frequencies of these resonance pairs, the magnetic field vector in all spatial coordinates may be reconstructed, enabling applications in wide-field magnetic imaging and nanoscale magnetometry.

A problem with ODMR system 200 is that it is too large in a typical optical bench implementation, and not particularly mobile, for use outside the laboratory.

A compact optical detection sensor system in accordance with aspects of the present disclosure overcomes the problems of size and mobility over that of ODMR system 200.

An aspect of the present disclosure is drawn to an optical waveguide that is configured to enable integrated scanning of quantum material.

Another aspect of the present disclosure is drawn to an optical sensor including a light source configured to provide light at an input wavelength λᵢ to an optical waveguide, an optical waveguide that is configured to enable integrated scanning of an array of QMCs with the light having an input wavelength λᵢ, an optical modulation portion that is configured to spatially modulate the light provided to the QMC array, a microwave generator configured to excite the QM within the QMC array with microwaves, and an imaging array configured to detect light having an emission wavelength λₑ as emitted by the QM within the QMC array.

Another aspect of the present disclosure is drawn to a system including the optical sensor discussed above and a controller configured to control the light source, to control the microwave generator, and to determine a parameter value at each of the QMCs based on an output by the imaging array.

In one or more embodiments, a wavelength tunable light source is placed at one end of the optical waveguide, with the quantum material at the other.

In one or more embodiments, the single tunable light source may be replaced by an array of light emitting diodes (LEDs), a vertical cavity surface-emitting laser (VCSEL) array, or grating antenna array fed via an optical waveguide operating over a frequency spectrum range.

In one or more embodiments, the optical waveguide is configured to convert some parameter of the light source into spatial scanning of the QMC array. The light source or array could be swept in wavelength, polarization, mode, or nearfield phase modulation.

In one or more embodiments, a spatial optical modulator is used in conjunction with the optical waveguide to convert these into spatial sweeps.

In one or more embodiments, the optical waveguide itself includes a spatial optical modulating portion to convert these into spatial sweeps.

The spatial optical modulator or the spatial optical modulating portion may optically modulate through known methods, non-limiting examples of which include: through diffractive layers, such as pillar arrays or phase rotators like metalenses; through refractive bends, such as metareflectors or special light modulators; gradient index (GRIN) sections that modify a refractive index based on spatial modification of material properties; and combinations thereof.

Known techniques for creating such a spatial optical modulating portion within an optical waveguide may be implemented, a non-limiting example of which includes laser processing techniques.

The optical waveguide may be fabricated out of known optical waveguide materials, non-limiting examples of which include silicon dioxide (glass), crystals, plastics, and combinations thereof. Within this larger optical waveguide, individual optical features (e.g., smaller waveguides, gratings, or other optical elements) may be fabricated using any known technique, non-limiting examples of which include laser writing, ion implantation, or other approaches.

At the exit of the optical waveguide, in one or more embodiments, a lenslet array or lenticular array may be placed before the QMC array to increase focusing efficiency onto the QMC array.

In one or more embodiments, each QMC of the QMC array may be the same type of quantum material.

In one or more embodiments, at least two QMCs of the QMC array may include different types of quantum material.

In one or more embodiments, the quantum material may be any quantum material, non-limiting examples of which include nitrogen-vacancy (NV) center diamond, silicon-vacancy (SiV) center diamond, tin-vacancy (SnV) center diamond, lead-vacancy (PbV) center diamond, nickel-vacancy (NiV) center diamond, color centers, hexagonal boron nitride (hBN) with defects, silicon carbide (SiC) with defects, or other spin sensitive material.

In one or more embodiments, the lenslet array (or lenticular array) may also have metallization crossbars or an antenna structure between the lenslets (or lenses) to apply microwave excitation to the quantum material in each QMC in the QMC array below.

In one or more embodiments, the QMC array can be arrayed on top of an imaging array (such as a CMOS camera sensor) where one or more pixel is dedicated to each QMC, as the purpose of the QMC is to absorb the source light at an input wavelength λᵢ and emit at second, different, emission wavelength λₑ. Non-limiting examples of an imaging array include a charge-coupled device (CCD), and active-pixel complementary metal-oxide-semiconductor (CMOS).

The amount of emission from each QMC corresponds to a parameter value at the location of that respective QMC. Non-limiting examples of such parameters include a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof.

In one or more embodiments, pixel level color (i.e., wavelength) filters may be applied to each pixel of the imaging array. In one or more of these embodiments, most pixel filters may be tuned to an emission wavelength λₑ of the QM, whereas some pixel filters may be tuned to the source light input wavelength λᵢ as a reference to eliminate effects of amplitude drift of the source light.

In one or more embodiments, if multiple pixels of the imaging array are dedicated to each QMC, a diffraction pattern from the chiplet may be analyzed, and high-resolution map of the parameter field can be created.

In one or more embodiments, a light baffle or baffles may be implemented to eliminate cross talk between optical waveguide paths, and to reduce cross-talk between QMCs.

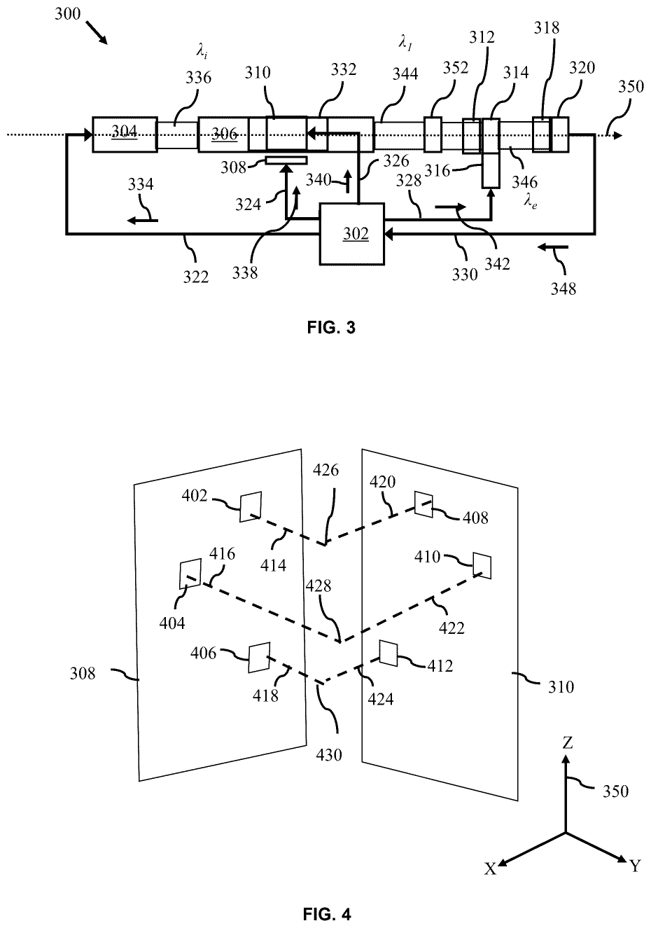

Example systems for optically detecting a field of a parameter using a QMC array in accordance with aspects of the present disclosure will now be described in greater detail with reference to FIGS. 3-22.

FIG. 3 illustrates a non-limiting example system 300 for optically detecting a field of a parameter using a QMC array in accordance with aspects of the present disclosure.

As shown in the figure, system 300 includes a controller 302, a laser array 304, an optical waveguide 306, a modulation controlling plate 308, a modulation controlling plate 310, a baffle 312, a QMC array 314, a microwave emitter 316, a baffle 318, an imaging array 320, a laser communication channel 322, a modulation controlling plate communication channel 324, a modulation controlling plate communication channel 326, a microwave emitter communication channel 328, and an imaging array communication channel 330. Optical waveguide 306 includes an optical modulation portion 332 therein.

In this example, controller 302, laser array 304, optical waveguide 306, modulation controlling plate 308, modulation controlling plate 310, baffle 312, QMC array 314, microwave emitter 316, baffle 318, and imaging array 320 are illustrated as individual devices. However, in one or more embodiments, at least two of controller 302, laser array 304, optical waveguide 306, modulation controlling plate 308, modulation controlling plate 310, baffle 312, QMC array 314, microwave emitter 316, baffle 318, and imaging array 320 may be combined as a unitary device. Further, in one or more embodiments, controller 302 may be implemented as a computer having non-transitory computer-readable media for carrying or having computer-executable instructions or data structures stored thereon. Such non-transitory computer-readable recording medium refers to any computer program product, apparatus or device, such as a magnetic disk, optical disk, solid-state storage device, memory, programmable logic devices (PLDs), DRAM, RAM, ROM, EEPROM, CD-ROM or other optical disk storage, magnetic disk storage or other magnetic storage devices, or any other medium that can be used to carry or store desired computer-readable program code in the form of instructions or data structures and that can be accessed by a general-purpose or special-purpose computer, or a general-purpose or special-purpose processor. Disk or disc, as used herein, includes compact disc (CD), laser disc, optical disc, digital versatile disc (DVD), floppy disk and Blu-ray disc. Combinations of the above are also included within the scope of computer-readable media. For information transferred or provided over a network or another communications connection (either hardwired, wireless, or a combination of hardwired or wireless) to a computer, the computer may properly view the connection as a computer-readable medium. Thus, any such connection may be properly termed a computer-readable medium. Combinations of the above should also be included within the scope of computer-readable media.

Example tangible computer-readable media may be coupled to controller 302 such that the processor may read information from and write information to the tangible computer-readable media. In the alternative, the tangible computer-readable media may be integral to controller 302. Controller 302 and the tangible computer-readable media may reside in an integrated circuit (IC), an ASIC, or large-scale integrated circuit (LSI), system LSI, super LSI, or ultra LSI components that perform a part or all of the functions described herein. In the alternative, controller 302 and the tangible computer-readable media may reside as discrete components.

Example tangible computer-readable media may be also coupled to systems, non-limiting examples of which include a computer system/server, which is operational with numerous other general purpose or special purpose computing system environments or configurations. Examples of well-known computing systems, environments, and/or configurations that may be suitable for use with computer system/server include, but are not limited to, personal computer systems, server computer systems, thin clients, thick clients, handheld or laptop devices, multiprocessor systems, microprocessor-based systems, set-top boxes, programmable consumer electronics, network PCs, minicomputer systems, mainframe computer systems, and distributed cloud computing environments that include any of the above systems or devices, and the like.

Such a computer system/server may be described in the general context of computer system-executable instructions, such as program modules, being executed by a computer system. Generally, program modules may include routines, programs, objects, components, logic, data structures, and so on, that perform particular tasks or implement particular abstract data types. Further, such a computer system/server may be practiced in distributed cloud computing environments where tasks are performed by remote processing devices that are linked through a communications network. In a distributed cloud computing environment, program modules may be located in both local and remote computer system storage media including memory storage devices.

In one or more embodiments, laser array 304, optical waveguide 306, modulation controlling plate 308, modulation controlling plate 310, baffle 312, QMC array 314, microwave emitter 316, baffle 318, and imaging array 320 are a unitary sensor to be positioned at a space to detect a field of a parameter and to be implemented so as to be spatially separated from controller 302.

In one or more embodiments, controller 302, laser array 304, optical waveguide 306, modulation controlling plate 308, modulation controlling plate 310, baffle 312, QMC array 314, microwave emitter 316, baffle 318, and imaging array 320 are a unitary system to be positioned at a space to detect a field of a parameter.

Controller 302 may be any device or system that is configured to control the operation of system 300.

Controller 302 is configured to: communicate with laser array 304 via laser communication channel 322; communicate with modulation controlling plate 308 via modulation controlling plate communication channel 324; communicate with modulation controlling plate 310 via modulation controlling plate communication channel 326; communicate with microwave emitter 316 via microwave emitter communication channel 328; and communicate with imaging array 320 via imaging array communication channel 330.

Laser array 304 may be any device or system that is configured to output n light beams, wherein n is a positive integer greater than 1. In one or more embodiments, laser array 304 may take the form of one of a group of light sources including a single tunable light source, an array of light emitting diodes (LEDs), an array of vertical-cavity surface-emitting lasers (VCSEL), a grating antenna array operating over a frequency spectrum range, and combinations thereof. In a non-limiting example embodiments described in more detail herein, merely for purposes of explanation, laser array 304 is a VCSEL array. In one or more embodiments, each laser of laser array 304 is configured to emit a respective light beam, wherein each light beam has the same input wavelength λᵢ. In one or more embodiments, at least one laser of laser array 304 is configured to emit a light beam, having an input wavelength λᵢ₁, that is different from an input wavelength λᵢ₂ of a light beam of at least one other laser of laser array 304.

For purposes of discussion, light from laser array 304 travels along an axis 350 to imaging array 320, which in this example is a straight line. As will be described in greater detail below, the axis of travel in one or more embodiments is not along a straight line.

Optical waveguide 306 is disposed to receive the n light beams output by laser array 304. Optical waveguide 306 may be any device or system that is configured to output m light beams, based on the received n light beams from laser array 304, to QMC array 314, wherein m is a positive integer greater than 0. In one or more embodiments, n equals m, wherein the number of light beams input into optical waveguide 306 is equal to the number of light beams output from optical waveguide 306. In one or more other embodiments, n is not equal to m, wherein the number of light beams input into optical waveguide 306 is not equal to the number of light beams output from optical waveguide 306. Optical waveguide 306 may be any known waveguide material, non-limiting examples of which include quartz, glass, plastic, and combinations thereof. As previously described, individual light paths or optical elements for light transport and/or conversion may be fabricated in optical waveguide 306 using any known technique to facilitate the transport of input-to-output light beams.

Optical modulation portion 332 may be any optical device or system that is configured to spatially modulate the n light beams from laser array 304, wherein optical waveguide 306 outputs the m light beams as m spatially modulated light beams to QMC array 314. In one or more embodiments, optical modulation portion 332 may take the form of one of a group of optical modulating elements including a wavelength modulating element, a polarization modulating element, a mode modulating element, a nearfield phase modulating element, a gradient index lex, a diffractive element, a refractive element, a lenticular array, an intensity modulating element, an actuatable modulation material to be used in conjunction with modulation controlling plate 308 and modulation controlling plate 308, and combinations thereof. Optical modulation portion 332 may be fabricated monolithically as a portion of optical waveguide 306.

Modulation controlling plate 308 is arranged adjacent to a portion of modulation material portion 332. Modulation controlling plate 308 may be any device or system that is configured to generate an actuating mechanism into a first set of selectable two-dimensional locations of modulation material portion 332.

Modulation controlling plate 310 is arranged adjacent to a second portion of modulation material portion 332 in a manner that is perpendicular to modulation controlling plate 308. Modulation controlling plate 310 may be any device or system that is configured to generate an actuating mechanism into a second set of selectable two-dimensional locations of optical modulation portion 332.

The operation of modulation controlling plate 308 and modulation controlling plate 310 will now be described in greater detail with reference to FIG. 4.

FIG. 4 illustrates an oblique view of modulation controlling plate 308 and modulation controlling plate 310 in accordance with aspects of the present disclosure.

As shown in the figure, modulation controlling plate 308 includes an array of actuators, a sample of which are indicated as actuator 402, actuator 404 and actuator 406. Modulation controlling plate 310 includes an array of actuators, a sample of which are indicated as actuator 408, actuator 410 and actuator 412.

Each actuator in modulation controlling plate 308 and modulation controlling plate 310 is able to provide an actuating mechanism into optical modulation portion 332 (not shown) along an axis that is normal to the surface of the actuator. For example, actuator 402 is able to provide an actuating mechanism along an axis 414 into optical modulation portion 332, actuator 404 is able to provide an actuating mechanism along an axis 416 into optical modulation portion 332, actuator 406 is able to provide an actuating mechanism along an axis 418 into optical modulation portion 332, actuator 408 is able to provide an actuating mechanism along an axis 420 into optical modulation portion 332, actuator 410 is able to provide an actuating mechanism along an axis 422 into optical modulation portion 332, and actuator 412 is able to provide an actuating mechanism along an axis 424 into optical modulation portion 332.

In such a manner, an actuating mechanism may not have a sufficient magnitude to alter the optical properties within optical modulation portion 332 along its axis. For example, the actuating mechanism from actuator 402 along axis 414 may not have sufficient magnitude to alter the optical properties within optical modulation portion 332 along the entirety of axis 414. Similarly, the actuating mechanism from actuator 408 along axis 420 may not have sufficient magnitude to alter the optical properties within optical modulation portion 332 along the entirety of axis 420. However, the combination of the magnitude of the actuation mechanism from actuator 402 along axis 414 and the magnitude of the actuation mechanism from actuator 408 along axis 420 may be sufficiently high at a location 426 within optical modulation portion 332 to alter the optical properties of optical modulation portion 332 at location 426. Similarly, the combination of the magnitude of the actuation mechanism from actuator 404 along axis 416 and the magnitude of the actuation mechanism from actuator 410 along axis 422 may be sufficiently high at a location 428 within optical modulation portion 332 to alter the optical properties of optical modulation portion 332 at location 428, and the combination of the magnitude of the actuation mechanism from actuator 406 along axis 418 and the magnitude of the actuation mechanism from actuator 412 along axis 424 may be sufficiently high at a location 430 within optical modulation portion 332 to alter the optical properties of optical modulation portion 332 at location 430.

In this manner, the optical properties of locations along an XYZ coordinate system (wherein the Z axis corresponds an axis 350 of optical waveguide 306 as shown in FIG. 3) within optical modulation portion 332 may be selectively altered so as to dynamically modulate light through optical waveguide 306.

In one or more embodiments, an actuator may be a laser, wherein the actuating mechanism is light so as to function as an all-optical modulator. In such embodiments, optical modulation portion 332 may include known nonlinear optical materials that exhibit changes in their optical properties when exposed to intense light, non-limiting examples of which include potassium dihydrogen phosphate, polymers with chromophores, and semiconductor nanostructures.

In one or more embodiments, an actuator may be a piezoelectric element, wherein the actuating mechanism is a pressure wave so as to function as a piezoelectric-optical modulator. In such embodiments, optical modulation portion 332 may include known optical materials that exhibit changes in their optical properties when exposed to pressure, non-limiting examples of which include zinc oxide, polyvinylidene fluoride, and barium titanate.

In one or more embodiments, an actuator may be a heating element, wherein the actuating mechanism is heat so as to function as a thermo-optical modulator. In such embodiments, optical modulation portion 332 may include known optical materials that exhibit changes in their optical properties when exposed to heat, a non-limiting example of which includes vanadium dioxide.

In one or more embodiments, an actuator may be a magnetic field generating element, wherein the actuating mechanism is a magnetic field so as to function as a magneto-optical modulator. In such embodiments, optical modulation portion 332 may include known optical materials that exhibit changes in their optical properties when exposed to a magnetic field, non-limiting examples of which include ferrofluids, magnetoplasmonic nanostructures, all-dielectric magnetic metasurfaces, and magnetic polymer composites.

In one or more embodiments, an actuator may be an electric field generating element, wherein the actuating mechanism is an electric field so as to function as an electro-optical modulator. In such embodiments, optical modulation portion 332 may include known optical materials that exhibit changes in their optical properties when exposed to an electric field, non-limiting examples of which include lithium niobate, barium titanate, potassium dihydrogen phosphate, organic polymers, and semiconductor materials.

Returning to FIG. 3, light baffle 312 is disposed between optical waveguide 306 and QMC array 314. Baffle 312 may be any device or system that is configured to prevent a light beam of the m spatially modulated light beams emitted from optical waveguide 306 from combining with another light beam of the m spatially modulated light beams emitted from optical waveguide 306 at any QMC within QMC array 314. Non-limiting examples of baffle 312 include opaque epoxy coatings applied in targeted regions of the device, isolated QM material packages, discrete component cavities or frames for the elements of the QMC array or any other non-limiting physical barrier that prevents light transmission or cross-talk.

QMC array 314 is disposed between baffle 312 and baffle 318 so as to receive the spatially modulated beams emitted from optical waveguide 306 that pass through baffle 312. QMC array 314 may be any device or system that is configured to have more than one chiplet of quantum material that is configured to absorb light at an input wavelength λᵢ and to emit light at an emission wavelength λₑ, wherein λᵢ≠λₑ. The quantum material may be any quantum material, non-limiting examples of which include NV center diamond, SiV center diamond, SnV center diamond, PbV center diamond, NiV center diamond, color centers, hBN with defects, SiC with defects, or other spin sensitive material.

In one or more embodiments, at least two QMCs of QMC array 314 include different types of quantum material.

In one or more embodiments, each QMC of QMC array 314 is configured to emit an emission light having the same emission wavelength λₑ based on the respective parameter value that includes one value of a group of parameter values including a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each QMC.

In one or more embodiments, each QMC of QMC array 314 is configured to emit a respective emission light having a respective emission wavelength λᵣₑ based on the respective parameter value that includes one value of a group of parameter values including a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each QMC.

In one or more embodiments, at least two QMCs of QMC array 314 are configured to emit a respective emission light having the same emission wavelength λₑ based on two different respective parameter values that includes two values of a group of parameter values including a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each QMC.

In one or more embodiments, at least two QMCs of QMC array 314 are configured to emit different respective emission lights having different respective emission wavelengths λᵣₑ based on a different respective parameter values that includes two values of a group of parameter values including a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each QMC.

Microwave emitter 316 may be any device or system that is configured to emit microwave pulses to QMC array 314. Microwave pulses from microwave emitter 316 drive transitions between the ground state spin states (ms=0 and ms=±1) of electrons in the QMCs of QMC array 314. Non-limiting examples of microwave emitter 316 include planar resonators, loop antennas, three-dimensional cavity resonators, microwave strip lines, coplanar waveguides, and horn antennas. In one or more embodiments, the microwave frequency is tuned around 2.87 GHz to match the zero-field splitting of the ground state of a NV center diamond.

Baffle 318 is disposed between QMC array 314 and imaging array 320. Baffle 318 may be any device or system that is configured to prevent light emitted from each QMC within QMC array 314 from combining with light from another QMC within QMC array 314 at imaging array 320. Non-limiting examples of baffle 318 include opaque epoxy coatings applied in targeted regions of the device, isolated QM material packages, discrete component cavities or frames for the elements of the QMC array or any other non-limiting physical barrier that prevents light transmission or cross-talk.

Imaging array 320 may be any device or system that is configured as an array to detect light at p discrete areas, wherein p is a positive integer greater than 1, and to output an imaging signal based on the light detected at each respective discreate area. In one or more embodiments, p is equal to m, wherein the number of discrete areas of imaging array 320 are equal to the number of light beams output from optical waveguide 306. In one or more other embodiments, p is not equal to m, wherein the number of discrete areas of imaging array 320 are not equal to the number of light beams output from optical waveguide 306. Non-limiting examples of imaging array 320 include a charge-coupled device (CCD), and active-pixel complementary metal-oxide-semiconductor (CMOS).

Laser communication channel 322, modulation plate controlling communication channel 324, modulation plate controlling communication channel 326, microwave emitter communication channel 328, and imaging array communication channel 330 may be any known type of communication channel including a wired and a wireless communication channel.

In operation, controller 302 outputs a laser driving signal 334 to laser array 304, via laser communication channel 322. Laser driving signal 334 causes laser array 304 to emit n light beams 336 having an input wavelength λᵢ into optical waveguide 306. Controller additionally outputs a modulator drive signal 338 to modulation controlling plate 308, via modulation controlling plate communication channel 324, and outputs a modulator drive signal 340 to modulation controlling plate 310 via modulation controlling plate communication channel 326. Controller additionally outputs a microwave driving signal 342 to microwave emitter 316, via microwave emitter communication channel 328. Microwave driving signal 342 causes microwave emitter 316 to emit microwaves into QMC array 314.

Optical modulation portion 332 spatially modulates n light beams 336 within optical waveguide 306 and outputs m spatially modulated light beams 344 having an input wavelength λᵢ. A field 352 of a parameter, e.g., a magnetic field, an electric field, temperature, strain, etc., is at or near QMC array 314 so as to affect light emitted from QMCs within QMC array 314. m spatially modulated light beams 344 are incident upon QMC array 314, whereas microwave emitter 316 emits microwaves into QMC array 314. m spatially modulated light beams 344 and the microwaves from microwave emitter 316 interact with the electrons in the QMCs within QMC array 314 in a manner similar to that discussed above with reference to FIGS. 1-2.

QMC array 314 outputs light 346 in emission wavelength λₑ, wherein λᵢ≠λₑ. As mentioned above, in one or more embodiments, light 346 may include a plurality of lights having a respective plurality of emission wavelengths λₑᵣ, wherein each of the respective plurality of emission wavelengths λₑᵣ≠λᵢ.

Imaging array 320 detects light 346 and outputs an imaging signal 348 to controller 302 via imaging array communication channel 330.

Controller displays an output corresponding to a value of the parameter of field 352 based on imaging signal 348.

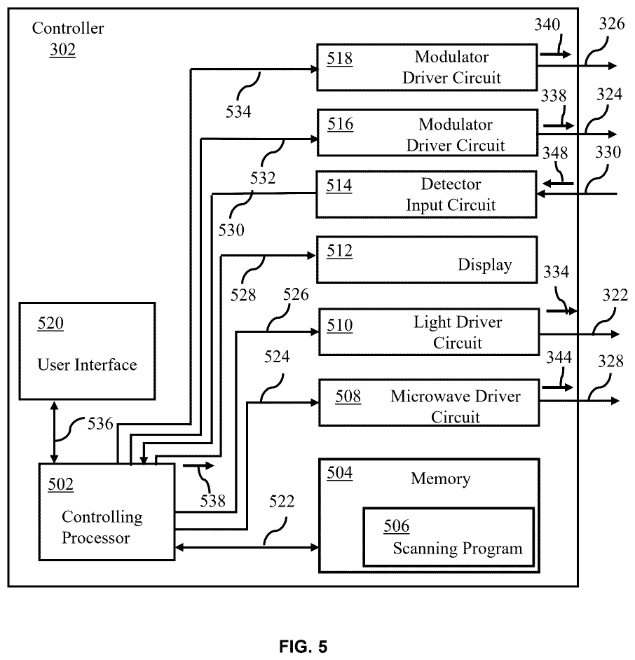

The operation of controller 302 will be described in greater detail with reference to FIG. 5.

FIG. 5 illustrates a non-limiting example of controller 302 of system 300 of FIG. 3.

As shown in FIG. 5, controller 302 includes a controlling processor 502, a memory 504 having data and a scanning program 506 stored therein, a microwave driver circuit 508, a light driver circuit 510, a display 512, a detector input circuit 514, a modulator driver circuit 516, a modulator driver circuit 518, a user interface (UI) 520, a memory communication channel 522, a microwave communication channel 524, a light driver communication channel 526, a display communication channel 528, a detector communication channel 530, a modulator communication channel 532, a modulator communication channel 534, and a UI communication channel 536.

In this example, controlling processor 502, memory 504, microwave driver circuit 508, light driver circuit 510, display 512, detector input circuit 514, modulator driver circuit 516, modulator driver circuit 518, and UI 520 are illustrated as individual devices. However, in one or more embodiments, at least two of controlling processor 502, memory 504, microwave driver circuit 508, light driver circuit 510, display 512, detector input circuit 514, modulator driver circuit 516, modulator driver circuit 518, and UI 520 may be combined as a unitary device. Further, in one or more embodiments, at least one of controlling processor 502, memory 504, microwave driver circuit 508, light driver circuit 510, display 512, detector input circuit 514, modulator driver circuit 516, modulator driver circuit 518, and UI 520 may be implemented as a computer having non-transitory computer-readable media for carrying or having computer-executable instructions or data structures stored thereon.

Controlling processor 502 is configured to: communicate with memory 504 via memory communication channel 522; communicate with microwave driver circuit 508 via microwave communication channel 524; communicate with light driver circuit 510 via light driver communication channel 526; communicate with display 512 via display communication channel 528; communicate with detector input circuit 514 via detector communication channel 530; communicate with modulator driver circuit 516 via modulator communication channel 532; communicate with modulator driver circuit 518 via modulator communication channel 534; and communicate with UI 520 via UI communication channel 536.

Controlling processor 502 may be any device or system that is configured to control the operation of controller 302.

Memory 504 may be any device or system capable of storing data, scanning program 506 and instructions used by controlling processor 502 and includes, but is not limited to, RAM, DRAM, a hard drive, a solid-state drive, ROM, EPROM, EEPROM, flash memory, embedded memory blocks in an FPGA, or any other various layers of memory hierarchy.

Microwave driver circuit 508 may be any device or system that is configured to output a microwave driver signal to microwave emitter 316 via microwave emitter communication channel 328.

Light driver circuit 510 may be any device or system that is configured to output laser driver signal to laser array 304 via laser communication channel 322.

Display 512 may be any device or system that is configured to display an output of controller 302 for a user.

Detector input circuit 514 may be any device or system that is configured to receive detected parameter signals from imaging array 320 via imaging array communication channel 330.

Modulator driver circuit 516 may be any device or system that is configured to output a modulator drive signal 338 to modulation controlling plate 308 via modulation controlling plate communication channel 324.

Modulator driver circuit 518 may be any device or system that is configured to output modulator drive signal 340 to modulation controlling plate 310 via modulation controlling plate communication channel 326.

UI 520 may be any device or system that is configured to enable a user to access and control controlling processor 502. UI 520 may include one or more layers including a human-machine interface (HMI) machines with physical input hardware such a keyboards, mice, game pads and output hardware such as computer monitors, speakers, and printers. Additional UI layers in UI 520 may interact with one or more human senses, including: tactile UI (touch), visual UI (sight), and auditory UI (sound).

Scanning program 506 controls the operations of controller 302. Scanning program 506, having a set (at least one) of program modules, may be stored in memory 504 by way of example, and not limitation, as well as an operating system, one or more application programs, other program modules, and program data. Each of the operating system, one or more application programs, other program modules, and program data or a combination thereof, may include an implementation of a networking environment. The program modules generally perform the functions and/or methodologies of various embodiments of the disclosure as described herein.

As will be described in greater detail below, in one or more embodiments, scanning program 506 includes instructions, that when executed by controlling processor 502, cause controller 302 to: cause a light source to generate input light having an input wavelength λᵢ; and determine a field of parameter values of QMC array 314 based on a detection signal from imaging array 320.

As will be described in greater detail below, in one or more embodiments, scanning program 506 includes instructions, that when executed by controlling processor 502, cause controller 302 to: cause laser array 304, as a light source, to generate input light having an input wavelength λᵢ; and determine a field of parameter values of QMC array 314 based on a detection signal from imaging array 320.

As will be described in greater detail below, in one or more embodiments, scanning program 506 includes instructions, that when executed by controlling processor 502, cause controller 302 to: cause a light source to generate input light having an input wavelength λᵢ; and determine a field of parameter values of QMC array 314 based on a detection signal from imaging array 320.

As will be described in greater detail below, in one or more embodiments, scanning program 506 additionally includes instructions, that when executed by controlling processor 502, cause controller 302 to: cause microwave emitter 316 to emit microwaves to QMC array 314.

As will be described in greater detail below, in one or more embodiments, scanning program 506 additionally includes instructions, that when executed by controlling processor 502, cause controller 302 to cause modulation controlling plate 308 to affect the optical properties of actuatable modulation material within optical modulation portion 332 of optical waveguide 306.

As will be described in greater detail below, in one or more embodiments, scanning program 506 additionally includes instructions, that when executed by controlling processor 502, cause controller 302 to cause modulation controlling plate 310 to affect the optical properties of actuatable modulation material within optical modulation portion 332 of optical waveguide 306.

As will be described in greater detail below, in one or more embodiments, scanning program 506 additionally includes instructions, that when executed by controlling processor 502, cause controller 302 to: cause modulation controlling plate 308 to affect the optical properties of actuatable modulation material within optical modulation portion 332 of optical waveguide 306; and cause modulation controlling plate 310 to affect the optical properties of actuatable modulation material within optical modulation portion 332 of optical waveguide 306.

Memory communication channel 522, microwave communication channel 524, light driver communication channel 526, display communication channel 528, detector communication channel 530, and UI communication channel 536 may be any known type of communication channel including a wired and a wireless communication channel.

In operation of one or more embodiments, controlling processor 502 executes instructions in scanning program 506 to instruct light driver circuit 510 to output laser driver signal 334. Laser array 304 then outputs n light beams 336 having an input wavelength λᵢ in response to laser driver signal 334.

In one or more embodiments, controlling processor 502 additionally executes instructions in scanning program 506 to instruct modulator driver circuit 516 to output modulator drive signal 338. Modulation controlling plate 308 provides at least one actuating mechanism into a portion of an actuatable modulation material within 332, in a manner as discussed above with reference to FIG. 4, in response to modulator drive signal 338. In one or more embodiments, controlling processor 502 additionally executes instructions in scanning program 506 to instruct modulator driver circuit 518 to output modulator drive signal 340. Modulation controlling plate 310 provides at least one actuation mechanism into a portion of the actuatable modulation material within 332, in a manner as discussed above with reference to FIG. 4, in response to modulator drive signal 340. In this manner, controller 302 is configured to dynamically optically spatially modulate n light beams 336 from laser array 304 to create m spatially modulated light beams 344 having an input wavelength λᵢ.

In one or more embodiments, controlling processor 502 additionally executes instructions in scanning program 506 to instruct microwave drive circuit 508 to output microwave driving signal 342.

Detector input circuit 514 transmits imaging signal 348 to controlling processor 502. Controlling processor 502 executes instructions in scanning program 506 to determine a value of the parameter of field 352 based on imaging signal 348. Controlling processor 502 outputs a display signal 538 to display 512 to cause display to display the determined value of the parameter of field 352.

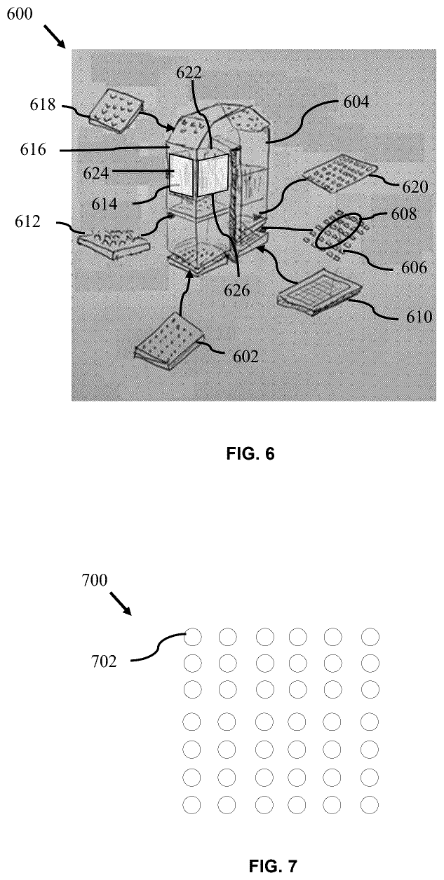

System 300 discussed above is illustrated more generally as a schematic to describe the operation of each element of the system. In accordance with one or more embodiments, an optical detector may include a laser array, waveguide, optical modulator, QMC array 314, microwave generator, and imaging array as a single device. This will be described in greater detail with reference to FIG. 6.

FIG. 6 illustrates an oblique view of a non-limiting example of an optical detector of magnetic resonance (ODMR) sensor 600 having a QMC array in accordance with aspects of the present disclosure.

As shown in the figure, ODMR sensor 600 includes a VCSEL array 602, an optical waveguide 604, a QMC array 606, a microwave emitting coil 608, an imaging array 610, and an optical modulating element. In one or more embodiments, the optical modulating element includes one or more of: one or more diffractive element 612; one or more dynamically optically spatially modulating element 614; one or more graded refractive index (GRIN) element 616; one or more refractive element 618; one or more lenslet array 620; and combinations thereof that may be fabricated monolithically into optical waveguide 604. One or more dynamically optically spatially modulating element 614 includes an actuatable modulation material 622 with a modulation controlling plate 624 facing one side and a modulation controlling plate 626 facing a perpendicular side.

VCSEL array 602 of ODMR sensor 600 corresponds to laser array 304 of system 300 discussed above with reference to FIG. 3. Optical waveguide 604 of ODMR sensor 600 corresponds to optical waveguide 306 of system 300. QMC array 606 of ODMR sensor 600 corresponds to QMC array 314 of system 300. Microwave emitting coil 608 of ODMR sensor 600 corresponds to microwave emitter 316 of system 300. Imaging array 610 of ODMR sensor 600 corresponds to imaging array 320 of system 300. The optical modulating element of ODMR sensor 600 corresponds to optical modulation portion 332 of system 300. In embodiments wherein the optical modulating element of ODMR sensor 600 includes a dynamically optically spatially modulating element 614, then modulation controlling plate 308, modulation controlling plate 310 and a portion of optical modulation portion 332 (not shown in FIG. 3) of system 300 correspond respectively to modulation controlling plate 624, modulation controlling plate 626 and actuatable modulation material 622.

In one or more embodiments, the optical modulating element is fabricated within optical waveguide 604.

In one or more embodiments, optical waveguide 604 includes at least two distinct pieces, wherein the optical modulating element is disposed between two of the distinct pieces.

In one or more embodiments, the optical modulating element is operable to spatially modulate light beams from VCSEL array 602. This will be described in greater detail with reference to the more general system 300 and FIG. 7.

FIG. 7 illustrates a cross-sectional view of example light beams emitted from a non-limiting example of laser array 304 of system 300 of FIG. 3.

As shown in FIG. 7, an array of light beams 700 includes a plurality of individual light beams, a sample of which is indicated as light beam 702. In this example, each laser of laser array 304 is emitting a respective light beam. Array of light beams 700 corresponds to light 336 of FIG. 3, being emitted from laser array 304 into optical waveguide 306.

An array of light beams similar to array of light beams 700 may be emitted from VCSEL array 602, of ODMR sensor 600 of FIG. 6, and into optical waveguide 604 of ODMR sensor 600 shown in FIG. 6.

Returning to FIG. 3, once in optical waveguide 306, the array of light beams from laser array 304 are modulated by optical modulation portion 332.

In one or more embodiments, optical modulation portion 332 optically spatially modulates light beams emitted by laser array 304 statically, dynamically, or a combination thereof.

By “statically,” optically spatially modulating light beams emitted by laser array 304, optical modulation portion 332 may take the form of one of a group of optical modulating elements including a wavelength modulating element, a polarization modulating element, a mode modulating element, a nearfield phase modulating element, a gradient index lex, a diffractive element, a refractive element, a lenticular array, an intensity modulating element, and combinations thereof. As such, once configured with optical waveguide 306, any optical spatial modulation will not change over time. On the contrary, it will stay the same, or be “static.”

However, by “dynamically,” optically spatially modulating light beams emitted by laser array 304, optical modulation portion 332 may take the form of an actuatable modulation material to be used in conjunction with modulation controlling plate 308.

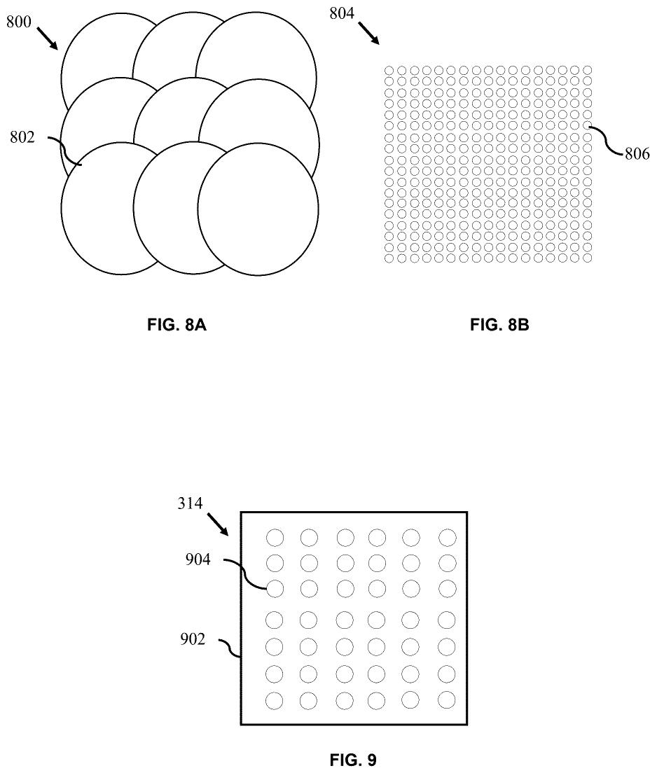

The results of optically spatially modulating light beams emitted by laser array 304 by optical modulation portion 332 will now be described in greater detail with reference to FIG. 8A-B.

FIG. 8A illustrates a cross-sectional view of example light beams emitted from non-limiting example laser array 304 of system 300 of FIG. 3, after having been spatially modulated in accordance with one or more embodiments.

As shown in FIG. 8A, an array of light beams 800 includes a plurality of individual light beams, a sample of which is indicated as light beam 802. In this example, each light beam from laser array 304 has been enlarged, so as to overlap multiple neighboring light beams. In one or more embodiments, the overlapping light beams may increase the amount of light onto distinct QMCs within QMC array 314. In one or more embodiments, the amount and specific shape of overlapping may be tailored via optical modulation portion 332 to create predetermined interference patterns to affect the amount of light onto distinct QMCs within QMC array 314.

FIG. 8B illustrates a cross-sectional view of example light beams emitted from non-limiting example laser array 304 of system 300 of FIG. 3, after having been spatially modulated in accordance with one or more other embodiments.

As shown in FIG. 8B, an array of light beams 804 includes a plurality of individual light beams, a sample of which is indicated as light beam 806. In this example, each light beam from laser array 304 has been reduced and split, so as to produce a larger number of smaller light beams. In one or more embodiments, the multiple smaller light beams may increase precision of light onto distinct QMCs within QMC array 314. In one or more embodiments, the size and number of split light beams may be tailored via optical modulation portion 332 to create predetermined targeting of light onto distinct QMCs within QMC array 314.

Array of light beams 800 or array of light beams 804 are examples that may correspond to m spatially modulated light beams 344 of FIG. 3, being emitted from optical waveguide 306 to QMC array 314.

An array of light beams similar to array of light beams 800 or array of light beams 804 may be emitted from optical waveguide 604 to QMC array 314 of system 300 as shown in FIG. 3 or QMC array 606 of ODMR sensor 600 shown in FIG. 6.

FIG. 9 illustrates a planar view of a non-limiting example of QMC array 314 of system 300 of FIG. 3.

As shown in FIG. 9, chiplet array 314 includes a substrate 902 having a plurality of areas of QMCs arranged in an array, an example of which is indicated as QMC 904.

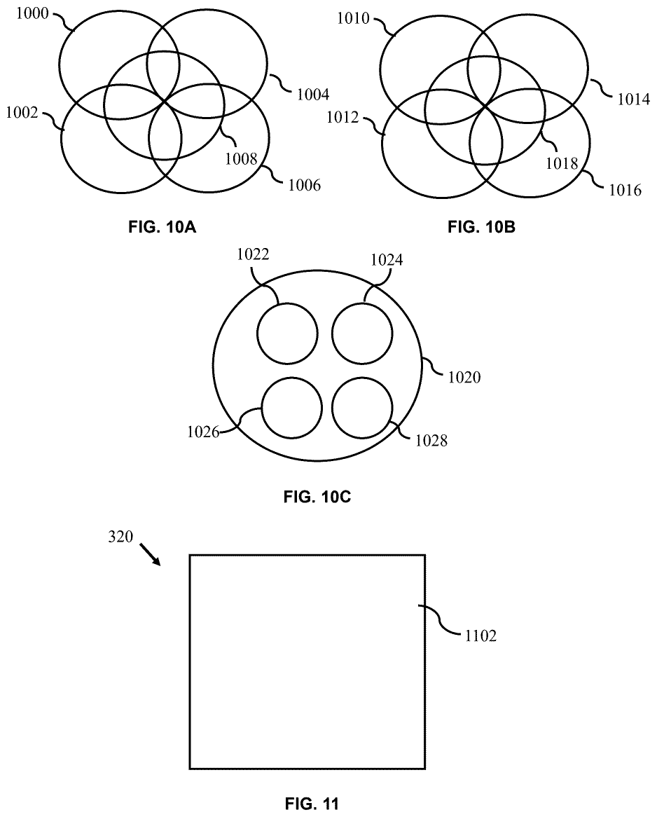

It should be noted that the amount of incident light on each QMC depends on the optical modulation by optical modulation portion 332 and by the size of the output light beams from each laser of laser array 304. This will be described in greater detail with reference to FIGS. 10A-C.

FIG. 10A illustrates overlapping light beams onto a single QMC in accordance with one or more embodiments.

As shown in the figure, a light beam 1000, a light beam 1002, a light beam 1004, and a light beam 1006, each being a portion of m spatially modulated light beams 344, are partially incident on a QMC 1008. Such an arrangement might increase the chance that at least one light beam may be incident on an NV center portion of QMC 1008.

However, it should be noted that in one or more embodiments, individual light beams of the m spatially modulated light beams 344 might interfere with one another. This will be described in greater detail with reference to FIG. 10B.

FIG. 10B illustrates overlapping light beams on a single QMC so as to create an interference pattern on the QMC in accordance with one or more embodiments,

As shown in the figure, a light beam 1010, a light beam 1012, a light beam 1014, and a light beam 1016, each being a portion of m spatially modulated light beams 344, are partially incident on a QMC 1018. In this case, light beams 1010, 1012, 1014, and 1016 create an interference pattern on QMC 1018. In one or more embodiments, the interference pattern created by the plurality of incident light beams may be predetermined so as to increase the amount of incident light onto a NV center portion of QMC 1018.

FIG. 10C illustrates a single light beam 1020 overlapping multiple QMCs in accordance with one or more embodiments. As shown in the figure, a light beam 1020 overlaps a QMC 1022, a QMC 1024, a QMC 1026 and a QMC 1028. Such an arrangement might increase the chance that each QMC has input light incident upon it.

After the QMCs of QMC array 314 are irradiated by m spatially modulated light beams 344, as mentioned above, the QMCs of QMC array 314 will emit light 346 to imaging array 320. This will be described in greater detail with reference to FIGS. 11-12B.

FIG. 11 illustrates a planar view of a non-limiting example of imaging array 320 of system 300 of FIG. 3 in accordance with one or more embodiments.

As shown in FIG. 11, imaging array 320 includes an array of discrete light detectors, a sample of which is indicated as light detector 1102.

In one or more embodiments, each light detector of imaging array may be sufficiently small such that a plurality of neighboring light detectors may detect light emitted from a single QMC of QMC array 314. This will be described in greater detail with reference to FIG. 12A.

FIG. 12A illustrates a single emission area overlapping a plurality of detecting cells of imaging array 320 in accordance with one or more embodiments.

As shown in the figure, a light detector 1200, a light detector 1202, a light detector 1204, and a light detector 1206 are configured such that each receives a portion of light emitted by a single QMC of QMC array 314, as shown by shaded circle 1208.

In one or more other embodiments, each light detector of imaging array may be sufficiently large such a single light detector may detect light emitted from a plurality of QMCs of QMC array 314. This will be described in greater detail with reference to FIG. 12B.

FIG. 12B illustrates a plurality of emission areas overlapping a single detecting cell of imaging array 320 in accordance with one or more embodiments.

As shown in the figure, a light detector 1210 is configured such that it receives light emitted by four different QMCs of QMC array 314, as shown by shaded circles 1212, 1214, 1216, and 1218.

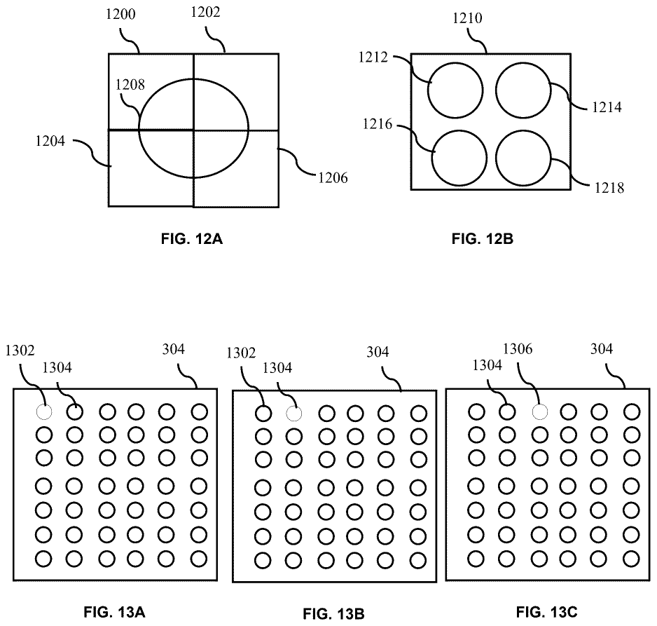

In the above-discussed non-limiting embodiments, each laser of laser array 304 emits light. As can be expected, in one or more embodiments, controller 302 can control laser array 304 to output a raster-scan of light beams into topical waveguide 306. This will be described in greater detail with reference to FIGS. 13A-C.

FIG. 13A illustrates a planar view of a non-limiting example of laser array 304 of system 300 of FIG. 3 in accordance with one or more embodiments at a time t₁.

As shown in FIG. 13A, laser array 304 includes an array of distinct laser emitters, an example of which is indicated as laser emitters 1302 and 1304. In this state, only laser emitter 1302 is emitting light, as indicated by the darkened circle, whereas the other laser emitters are not emitting light, as indicated by the non-darkened circles such as laser emitter 1304.

In these non-limiting embodiments, controller 302 outputs laser driving signal 334 to cause laser array 304 to drive less than all lasers within laser array 304 at the same time. In one or more embodiments, controller 302 outputs laser driving signal 334 to cause laser array 304 to raster scan the laser within laser array 304. This will be described in greater detail with reference to FIGS. 13B-C.

FIG. 13B illustrates a planar view of non-limiting example of laser array 304 of FIG. 13A at a time t₂.

As shown in FIG. 13B, only laser emitter 1304 is emitting light, as indicated by the darkened circle, whereas the other laser emitters are not emitting light, as indicated by the non-darkened circles such as laser emitter 1302.

FIG. 13C illustrates a planar view of non-limiting example of laser array 304 of FIG. 13B at a time t₃.

As shown in FIG. 13C, only laser emitter 1306 is emitting light, as indicated by the darkened circle, whereas the other laser emitters are not emitting light, as indicated by the non-darkened circles such as laser emitter 1304.

In the non-limiting example embodiments discussed above with reference to FIGS. 13A-C, controller 302 controls laser array 304 to output in a raster scan mode of illuminating each QMC within QMC array 314. However, in one or more embodiments, individual laser emitters may be activated so as to illuminate predetermined QMCs within QMC array 314.

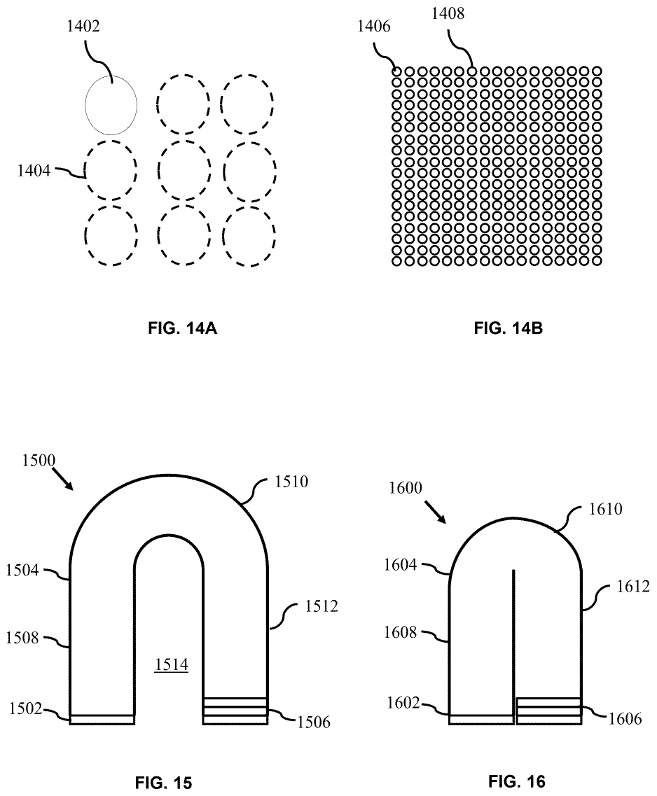

Returning to FIG. 3, after being emitted into optical waveguide 306, light 336 is optically spatially modulated by optical modulation portion 332 to produce m spatially modulated light beams 344. m spatially modulated light beams 344 are then incident upon QMC array 314. This will be described in greater detail with reference to FIGS. 14A-B.

FIG. 14A illustrates a cross-sectional view of example light beams emitted from non-limiting example of laser array 304 of FIGS. 13A-C, after having been spatially modulated by optical modulation portion 332 in accordance with one or more embodiments at a time t₄. As shown in the figure, a single spatially modulated light beam 1402 is emitted from optical modulation portion 332. A plurality of dashed circles, a sample of which is indicated by dashed circle 1404, represent where other light beams may optionally be emitted from optical modulation portion 332.

FIG. 14B illustrates a cross-sectional view of example light beams emitted from non-limiting example of laser array 304 of FIGS. 13A-C, after having been spatially modulated by optical modulation portion 332 in accordance with one or more other embodiments at a time t₅. As shown in the figure, a single spatially modulated light beam 1406 is emitted from optical modulation portion 332. A plurality of circles, a sample of which is indicated by circle 1408, represent where other light beams may optionally be emitted from optical modulation portion 332.

As shown in FIGS. 14A-B, optical modulation portion 332 can alter the shape and size of light beams emitted by the individual lasers of laser array 304 by way of at least one of refraction, diffraction, and interference. Further, additional refraction, diffraction and interference effects may be tailored to result in predetermined specific outputs by optical modulation portion 332 by altering the number or location of driven individual lasers of laser array 304.

In one or more embodiments, it may be desired to prevent individual output light beams from optical modulation portion 332 to be incident on more than one QMC within QMC array 314 or to prevent more than one individual output light beam from spatial optical modulation portion to be incident on a single QMC within QMC array 314. Accordingly, in one or more embodiments, as discussed above, baffle 312 reduces cross-talk between light beams incident onto QMCs within QMC array 314.

In one or more embodiments, it may be desired to prevent light emitted from each QMC within QMC array 314 from combining with light from another QMC within QMC array 314 at imaging array 320. Accordingly, in one or more embodiments, as discussed above, baffle 318 prevents light emitted from each QMC within QMC array 314 from combining with light from another QMC within QMC array 314 at imaging array 320.

FIG. 6 illustrates a non-limiting example shape of an optical detector in accordance with one or more embodiments. However, other shapes of optical detectors may be configured in accordance with aspects of the present disclosure, some non-limiting examples of which will now be described in greater detail with reference to FIGS. 15-19.

FIG. 15 illustrates a front view of a non-limiting example of a horseshoe-shaped integrated optical sensor (IOS) 1500 in accordance with one or more embodiments.

As shown in the figure, horseshoe-shaped IOS 1500 includes a laser array 1502, a waveguide body 1504, and an output processing portion 1506. Output processing portion 1506 is illustrated for brevity, but may include at least one of a QMC array, a microwave emitter, an imaging array, and a baffle as discussed above with reference to FIG. 3.

Waveguide body 1504 includes an input leg 1508, a turning portion 1510, and an output leg 1512. Input leg 1508 is configured to receive light from laser array 1502 and pipe the light to turning portion 1510. Turning portion 1510 is configured to receive light from input leg 1508 and pipe the light to output leg 1512. Output leg 1512 is configured to receive light from the turning portion 1510 and pipe the light to output processing portion 1506.

Input leg 1508 is separated from output leg 1512 by a space 1514. In this manner, laser array 1502 may be displaced from an area to be detected by output processing portion 1506. Further, in a manner similar to the embodiments discussed above, waveguide body 1504 may include an optical modulating element that includes one or more of a diffractive element, GRIN element, a refractive element, and lenslet array, an actuatable modulation material portion in conjunction with modulation controlling plates, and combinations thereof.

FIG. 16 illustrates a front view of a non-limiting example of a U-shaped IOS 1600 in accordance with one or more embodiments.

As shown in the figure, U-shaped IOS 1600 includes a laser array 1602, a waveguide body 1604, and an output processing portion 1606. Output processing portion 1606 is illustrated for brevity, but may include at least one of a QMC array, a microwave emitter, an imaging array, and a baffle as discussed above with reference to FIG. 3.

Waveguide body 1604 includes an input leg 1608, a turning portion 1610, and an output leg 1612. Input leg 1608 is configured to receive light from laser array 1602 and pipe the light to turning portion 1610. Turning portion 1610 is configured to receive light from input leg 1608 and pipe the light to output leg 1612. Output leg 1612 is configured to receive light from output leg 1612 and pipe the light to output processing portion 1606.

Input leg 1608 is adjacent to output leg 1612, thus having no space as compared to horseshoe-shaped IOS 1500 discussed above. Further, in a manner similar to the embodiments discussed above, waveguide body 1604 may include an optical modulating element that includes one or more of a diffractive element, GRIN element, a refractive element, and lenslet array, an actuatable modulation material portion in conjunction with modulation controlling plates, and combinations thereof.

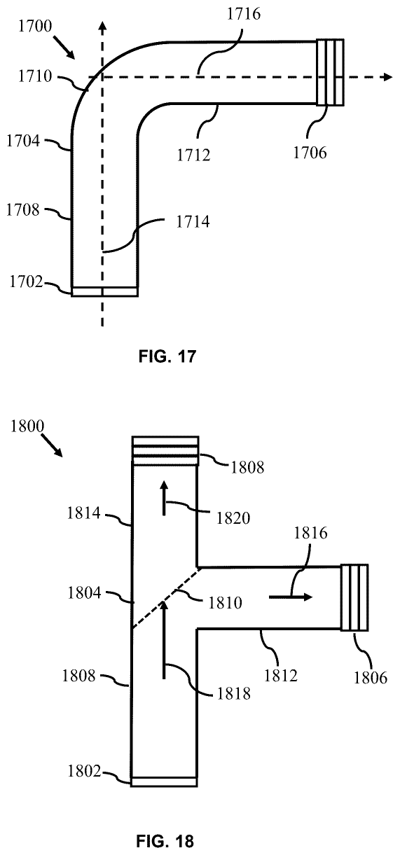

FIG. 17 illustrates a front view of a non-limiting example of a 90°-angle-turn-shaped IOS 1700 in accordance with one or more embodiments.

As shown in the figure, 90°-angle-turn-shaped IOS 1700 includes a laser array 1702, a waveguide body 1704, and an output processing portion 1706. Output processing portion 1706 is illustrated for brevity, but may include at least one of a QMC array, a microwave emitter, an imaging array, and a baffle as discussed above with reference to FIG. 3.

Waveguide body 1704 includes an input leg 1708, a turning portion 1710, and an output leg 1712. Input leg 1708 is configured to receive light from laser array 1702 and pipe the light to turning portion 1710. Turning portion 1710 is configured to receive light from input leg 1708 and pipe the light to output leg 1712. Output leg 1712 is configured to receive light from the turning portion 1710 and pipe the light to output processing portion 1706.

Input leg 1708 is configured to pipe light along an axis 1714, whereas output leg 1712 is configured to pipe light along an axis 1716. In this manner, laser array 1702 may be displaced from an area to be detected by output processing portion 1706. Further, in a manner similar to the embodiments discussed above, waveguide body 1704 may include an optical modulating element that includes one or more of a diffractive element, GRIN element, a refractive element, and lenslet array, an actuatable modulation material portion in conjunction with modulation controlling plates, and combinations thereof.

FIG. 18 illustrates a front view of a non-limiting example of a dual-output-split-shaped IOS 1800 in accordance with one or more embodiments.

As shown in the figure, dual-output-split-shaped IOS 1800 includes a laser array 1802, a waveguide body 1804, an output processing portion 1806, and an output processing portion 1808. Output processing portion 1806 is illustrated for brevity, but may include at least one of a QMC array, a microwave emitter, an imaging array, and a baffle as discussed above with reference to FIG. 3. Similarly, processing portion 1808 is illustrated for brevity, but may include at least one of a QMC array, a microwave emitter, an imaging array, and a baffle as discussed above with reference to a FIG. 3.

In one or more embodiments, the QMC array of output processing portion 1806 is similar to the QMC array of output processing portion 1808, wherein each will be able to output light based on a field at or near the QMC array, wherein the field is based on some parameter, e.g., a magnetic field, an electric field, temperature, strain. For example, output processing portion 1806 may be configured to output light based on a field at its QMC array, wherein the field is based on a magnetic field at or near the location of output processing portion 1806, and output processing portion 1808 may be configured to output light based on a field at its QMC array, wherein the field is similarly based on a magnetic field at or near output processing portion 1808.

In one or more embodiments, the QMC array of output processing portion 1806 is different than the QMC array of output processing portion 1808, wherein each will be able to output light based on a different type of field at or near the QMC array, wherein each respective field is based on a different respective parameter, e.g., a magnetic field, an electric field, temperature, strain. For example, output processing portion 1806 may be configured to output light based on a field at its QMC array, wherein the field is based on a magnetic field at or near the location of output processing portion 1806, and output processing portion 1808 may be configured to output light based on a field at its QMC array, wherein the field is based on a strain field at or near output processing portion 1808.

Waveguide body 1804 includes an input leg 1808, a beam splitter 1810, an output leg 1812, and an output leg 1814. Input leg 1808 is configured to receive light from laser array 1802 and pipe the light to beam splitter 1810. Beam splitter 1810 is configured to receive light from input leg 1808 as indicated by arrow 1818, reflect a portion of the received light into output leg 1812 as indicated by arrow 1816, and transmit a portion of the received light into output leg 1814 as indicated by arrow 1820. Output leg 1812 is configured to receive light that is reflected by beam splitter 1810 and pipe the light to output processing portion 1806. Output leg 1814 is configured to receive light that is transmitted through beam splitter 1810 and pipe the light to output processing portion 1808.

In this manner, laser array 1802 may be displaced from two separate areas on different axes to be detected by output processing portion 1806 and 1808, respectively. Further, in a manner similar to the embodiments discussed above, waveguide body 1804 may include an optical modulating element that includes one or more of a diffractive element, GRIN element, a refractive element, and lenslet array, an actuatable modulation material portion in conjunction with modulation controlling plates, and combinations thereof.

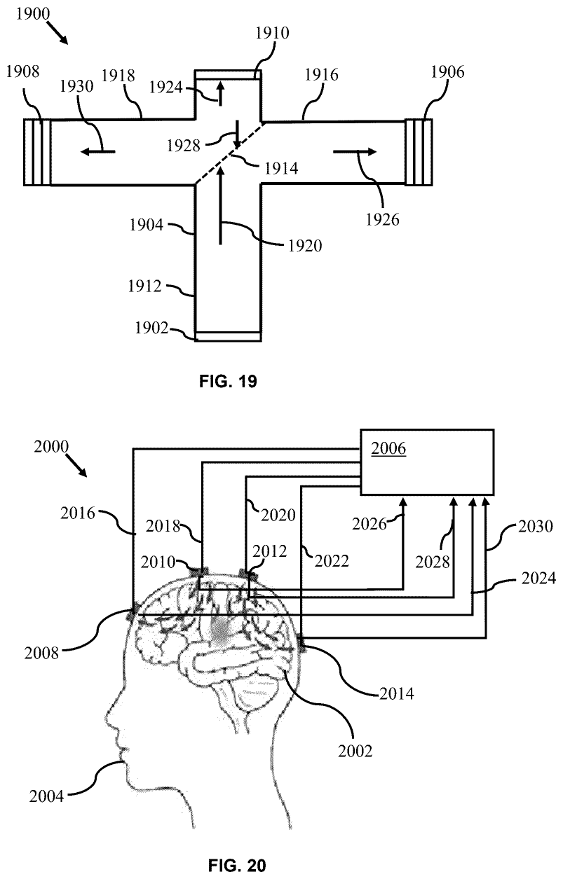

FIG. 19 illustrates a front view of a non-limiting example of a dual-output-T-shaped IOS 1900 in accordance with one or more embodiments.

As shown in the figure, dual-output-T-shaped IOS 1900 includes a laser array 1902, a waveguide body 1904, an output processing portion 1906, an output processing portion 1908, and a 1/4 waveplate mirror 1910. Output processing portion 1906 is illustrated for brevity, but may include at least one of a QMC array, a microwave emitter, an imaging array, and a baffle as discussed above with reference to any of FIG. 8, and 19-21. Similarly, processing portion 1908 is illustrated for brevity, but may include at least one of a QMC array, a microwave emitter, an imaging array, and a baffle as discussed above with reference to FIG. 3.

In one or more embodiments, the QMC array of output processing portion 1906 is similar to the QMC array of output processing portion 1908, wherein each will be able to output light based on a field at or near the QMC array, wherein the field is based on some parameter, e.g., a magnetic field, an electric field, temperature, strain. For example, output processing portion 1906 may be configured to output light based on a field at its QMC array, wherein the field is based on a magnetic field at or near the location of output processing portion 1906, and output processing portion 1908 may be configured to output light based on a field at its QMC array, wherein the field is similarly based on a magnetic field at or near output processing portion 1908.

In one or more embodiments, the QMC array of output processing portion 1906 is different than the QMC array of output processing portion 1908, wherein each will be able to output light based on a different type of field at or near the QMC array, wherein each respective field is based on a different respective parameter, e.g., a magnetic field, an electric field, temperature, strain. For example, output processing portion 1906 may be configured to output light based on a field at its QMC array, wherein the field is based on a magnetic field at or near the location of output processing portion 1906, and output processing portion 1908 may be configured to output light based on a field at its QMC array, wherein the field is based on a strain field at or near output processing portion 1908.

Waveguide body 1904 includes an input leg 1912, a beam splitter 1914, an output leg 1916, and an output leg 1918. Input leg 1912 is configured to receive light from laser array 1902, as indicated by arrow 1920, and pipe the light to beam splitter 1914. Beam splitter 1914 is configured to receive light from input leg 1912, reflect a portion of the received light into output leg 1916 as indicated by arrow 1926, and transmit a portion of the received light to 1/4 waveplate mirror 1910 as indicated by arrow 1924.

Output leg 1916 is configured to receive light that is reflected by beam splitter 1914 and pipe the light, as indicated by arrow 1926, to output processing portion 1906.

¼ waveplate mirror 1910 is configured to receive light that is transmitted by beam splitter 1914, as indicated by arrow 1924, perform a ¼ polarization change on the light and reflect the ¼ polarization changed light back toward beam splitter 1914 as indicated by arrow 1928. Output leg 1918 is configured to receive light that is reflected by beam splitter 1914 and pipe the light, as indicated by arrow 1930, to output processing portion 1908.

In this manner, laser array 1902 may be displaced from two separate areas to be detected on the same axis by output processing portion 1906 and 1908, respectively. Further, in a manner similar to the embodiments discussed above, waveguide body 1904 may include an optical modulating element that includes one or more of a diffractive element, GRIN element, a refractive element, and lenslet array, an actuatable modulation material portion in conjunction with modulation controlling plates, and combinations thereof.

In one or more embodiments, a single controller may control a plurality of IOSs. This will be described in greater detail with reference to FIGS. 20-21.

FIG. 20 illustrates a system 2000 for use to detect magnetic fields within a brain 2002 of a person 2004, in accordance with aspects of the present disclosure.

As shown in the figure, system 2000 includes a controller 2006, an IOS 2008, an IOS 2010, an IOS 2012, an IOS 2014, a control channel 2016, a control channel 2018, a control channel 2020, a control channel 2022, an output channel 2024, an output channel 2026, an output channel 2028, and an output channel 2030.

Controller 2006 is configured to: communicate with IOS 2008 via control channel 2016; communicate with IOS 2010 via control channel 2018; communicate with IOS 2012 via control channel 2020; and communicate with IOS 2014 via control channel 2022. Controller 2006 is additionally configured to: communicate with IOS 2008 via output channel 2024; communicate with IOS 2010 via output channel 2026; communicate with IOS 2012 via output channel 2028; and communicate with IOS 2014 via output channel 2030.

Controller 2006 that is configured to control the operation of system 2000.

Each of IOSs 2008, 2010, 2012, and 2014 may take the form of an IOS in accordance with aspects of the present disclosure, non-limiting examples of which include the IOSs discussed above with reference to FIGS. 26-30, wherein each is configured such the light output by each respective IOS is based on a magnetic field at or near the location of the respective IOS.

Each of control channels 2016, 2018, 2020, and 2022 is illustrated as a single respective channel, for purposes illustration only. In actuality, each of control channels 2016, 2018, 2020, and 2022 may include a control channel to control a laser array, a control channel to control microwave emitter, and (if included) control channels to control modulation control plates as discussed above with reference to FIGS. 8 and 19-22.

In operation, controller 2006 controls the respective laser arrays, microwave emitters, and, if included, the modulation control plates of each IOS. Each IOS then provides a respective output signal based on a detected magnetic field near its location within brain 2002. In this manner, controller 2006 may map magnetic fields within brain 2002. It should be noted that this non-limiting example embodiment includes 4 IOSs, however any number of IOSs may be used in accordance with aspects of the present disclosure.

FIG. 21 illustrates a system 2100 for use to detect strain on the surface of an aircraft wing 2102, in accordance with aspects of the present disclosure.

As shown in the figure, system 2100 includes: a controller 2104; a plurality of IOSs, a sample of which are indicated as IOS 2106 and IOS 2108; a plurality of control channels, a sample of which are indicated as control channel 2110 and control channel 2112; and a plurality of output channels, a sample of which are indicated as output channel 2114 and output channel 2116. It should be noted that control channels and output channels for the remaining IOSs are included, but are not illustrated to simplify the figure.

Controller 2104 is configured to communicate with each IOS via a respective control channel and via a respective output channel. Controller 2104 that is configured to control the operation of system 2100.

Each of the IOSs may take the form of an IOS in accordance with aspects of the present disclosure, non-limiting examples of which include the IOSs discussed above with reference to FIGS. 6 and 15-19, wherein each is configured such the light output by each respective IOS is based on a strain field at or near the location of the respective IOS.

Each control channels is illustrated as a single respective channel, for purposes illustration only. In actuality, each of the control channels may include a control channel to control a laser array, a control channel to control microwave emitter, and (if included) control channels to control modulation control plates as discussed above with reference to FIGS. 3-5.

Aircraft wing includes an upper surface 2118 and a lower surface 2120. Upper surface 2118 has a larger curvature than lower surface 2120 so as to create a longer path for which air has to travel. Specifically, while moving through air 2122, air 2122 is split such that a portion 2124 travels along upper surface 2118 and a portion 2126 travels along lower surface 2120. The larger curvature of upper surface 2118 causes portion 2124 to travel at a higher velocity than portion 2126, creating lift in accordance with the well-known Bernoulli principle.

However, while always present, forces on aircraft wing 2102 caused by movement through the air may constantly change. Further, such forces may not be constant throughout different locations of aircraft wing 2102. As such, system 2100 may precisely monitor stress at different portions of the surface of aircraft wing 2102.

In operation, controller 2104 controls the respective laser arrays, microwave emitters, and, if included, the modulation control plates of each IOS. Each IOS then provides a respective output signal based on a detected strain field near its location within aircraft wing 2102. In this manner, controller 2104 may map strain fields within aircraft wing 2102. It should be noted that this non-limiting example embodiment includes 9 IOSs, however any number of IOSs may be used in accordance with aspects of the present disclosure.

In system 2100, each IOS is configured to detect stress. However, in accordance with one or more embodiments, at least one IOS is configured to detect a parameter other than stress.

For example, in one or more embodiments, one or more IOSs of system 2100 may be configured to output light based on a strain field, whereas other IOSs may be configured to output light based on an electric field. In this manner, system 2100 may precisely monitor stress at different portions of aircraft wing 2102, and may additionally precisely monitor electric fields at different portion of aircraft wing 2102. Therefore, controller 2104 may map strain fields and electric fields at the surface of aircraft wing 2102.

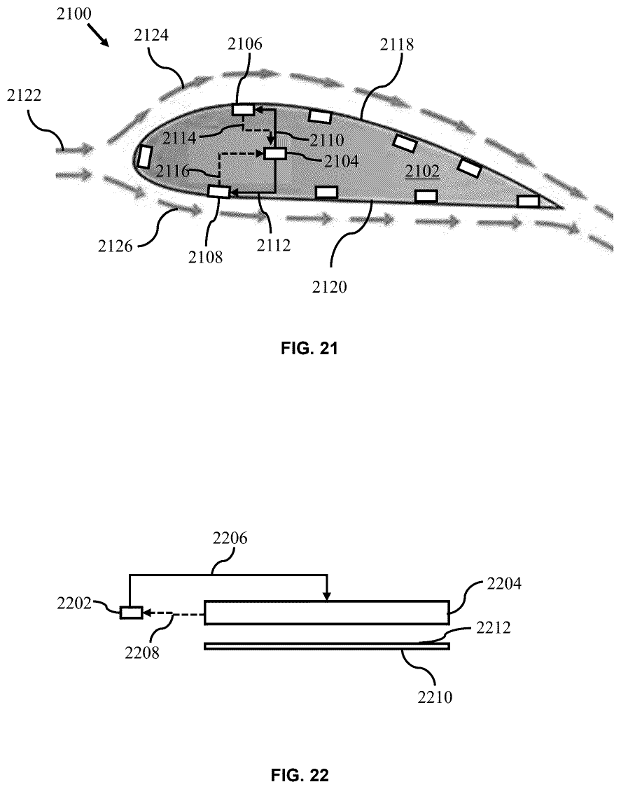

FIG. 22 illustrates a system for use to detect magnetic fields on the surface of an integrated circuit (IC) chip, in accordance with aspects of the present disclosure.

As shown in the figure, the system includes: a controller 2202; an IOS 2204; a control channel 2206; and an output channel 2208.

Controller 2202 is configured to communicate with IOS 2204 via control channel 2206 and via output channel 2208. Controller 2202 that is configured to control the operation of 2204.

IOS 2204 may take the form of an IOS in accordance with aspects of the present disclosure, non-limiting examples of which include the IOSs discussed above with reference to FIGS. 6 and 15-29, wherein each is configured such the light output by each respective IOS is based on a strain field at or near the location of the respective IOS.

Control channel 2206 is illustrated as a single respective channel, for purposes illustration only. In actuality, control channel 2206 may include a control channel to control a laser array, a control channel to control microwave emitter, and (if included) control channels to control modulation control plates as discussed above with reference to FIGS. 3-5.

IC chip 2210 includes an upper surface 2212, having circuit elements thereon. In operation, the circuit element on upper surface 2212 will generate respective magnetic and electric fields as a function of time.

Controller 2202 controls the respective laser arrays, microwave emitters, and, if included, the modulation control plates of IOS 2204. IOS 2204 then provides a respective output signal based on a detected magnetic (or electrically-induced magnetic) field near IC chip 2210. In this manner, controller 2202 may map the magnetic fields about the surface of IC chip 2210.

The system in FIG. 22 is configured to detect magnetic fields at the surface of IC chip 2210. However, in accordance with one or more embodiments, a system may be configured to detect a parameter other than the magnetic field.

For example, in one or more embodiments, an IOS may be configured to output light based on a heat field. In this manner, the system may precisely monitor heat at different portions of IC chip 2210.

A laser array in an IOS in accordance with aspects of the present disclosure enables precise and customizable light profiles for optical detection using quantum material, as discussed above for example with reference to FIGS. 11 and 13A-C. An optical spatial modulation portion in an IOS in accordance with aspects of the present disclosure enables further precise and customizable light profiles for optical detection using quantum, material, as discussed above for example with reference to FIGS. 8A-12B, and 14A-B.

A combination of a laser array and an optical spatial modulation portion, enables an easily customizable IOS for optical detection using quantum material, wherein an input array of light may interact with an array of QMCs in any one of: a one-to-one manner, wherein a single input light beam interacts with a single designated QMC; a one-to-many manner, wherein a single input light beam interacts with more than one QMC; and a many-to-one manner, wherein more than one input light beams interact with one QMC.

Further, the compact design of an IOS for optical detection using quantum material in accordance with aspects of the present disclosure enables and such an IOS to be easily transferred through commerce for use by an end user or end using system.

In one or more embodiments, in a system for optically detecting a field of a parameter using a QMC array in accordance with aspects of the present disclosure, all lasers from a laser array may emit light simultaneously. In one or more of these embodiments, light from each laser in the laser array may be optically modulated.

In one or more embodiments, in a system for optically detecting a field of a parameter using a QMC array in accordance with aspects of the present disclosure, each laser from a laser array may emit light as individually activated. In one or more of these embodiments, light from each laser may be optically modulated.

In one or more embodiments, the quantum material in each QMC with a QMC array may be the same. For example: the quantum material in each QMC with a QMC array may be a NV center diamond, SiV center diamond, SnV center diamond, PbV center diamond, NiV center diamond, color centers, hBN with defects, SiC with defects, or other spin sensitive material.

In one or more embodiments, at least one quantum material of a QMC in a QMC array is different from another quantum material of another QMC in the same QMC array. For example: the quantum material in at least one QMC with a QMC array may be a NV center diamond, SiV center diamond, SnV center diamond, PbV center diamond, NiV center diamond, color centers, hBN with defects, SiC with defects, or other spin sensitive material, whereas the quantum material in at least one other QMC with the QMC array may be a different one of a NV center diamond, SiV center diamond, SnV center diamond, PbV center diamond, NiV center diamond, color centers, hBN with defects, SiC with defects, or other spin sensitive material. In this manner, the different QMCs may output a light based on a differently detected parameter.

In one or more embodiment, all the QMCs in a chiplet array are configured to output light based on the same parameter at or near the respective QMC. For example: the quantum material in each QMC with a QMC array may be a quantum material that is configured to output light based on a magnetic field, electric fields, heat field, stress field, at or near the QMC.

In one or more embodiments, at least one QMC in a chiplet array is configured to output light based on a different parameter of at least one other QMC in the chiplet array at or near the respective QMCs. For example: the quantum material in at least one QMC with a QMC array may be a quantum material that is configured to output light based on one of a magnetic field, an electric fields, a heat field, a stress field, at or near the quantum material, whereas at least one other quantum material in a QMC with the same QMC array may be a quantum material that is configured to output light based on another different one of a magnetic field, an electric fields, a heat field, a stress field, at or near the quantum material.

The foregoing description of various preferred embodiments have been presented for purposes of illustration and description. It is not intended to be exhaustive or to limit the invention to the precise forms disclosed, and obviously many modifications and variations are possible in light of the above teaching. The example embodiments, as described above, were chosen and described in order to enable others skilled in the art to best utilize the invention in various embodiments and with various modifications as are suited to the particular use contemplated. It is intended that the scope of the invention be defined by the claims appended hereto.

What is claimed is:

1. A sensor comprising:
a light source configured to generate input light having an input wavelength λᵢ;
an optical waveguide;
an array of a plurality of quantum material chiplets; and
an imaging array,
wherein said optical waveguide is configured to transmit the input light to said array of said plurality of quantum material chiplets,
wherein each quantum material chiplet is configured to absorb a portion of the input light from said optical waveguide and to emit a respective emission light having a respective emission wavelength λᵣₑ in response to the absorption of the portion of the input light and based on a respective parameter value at each quantum material chiplet, and
wherein said imaging array is configured to detect each respective emission light and output a detection signal based on the respective parameter value at each quantum material chiplet.

2. The sensor of claim 1, wherein said light source comprises one of a group of light sources comprising a single tunable light source, an array of light emitting diodes, an array of vertical-cavity surface-emitting lasers, a grating antenna array operating over a frequency spectrum range, and combinations thereof.

3. The sensor of claim 1, further comprising:
a microwave emitter configured to emit microwave pulses to said array of said plurality of quantum material chiplets; and
an optical modulating element configured to modulate the input light.

4. The sensor of claim 3,
wherein said optical waveguide includes an optical modulation portion that includes said optical modulating element, and
wherein said optical modulating element comprises one of a group of optical modulating elements comprising a wavelength modulating element, a polarization modulating element, a mode modulating element, a nearfield phase modulating element, a gradient index lens, a diffractive element, a refractive element, a lenticular array, an intensity modulating element, and combinations thereof.

5. The sensor of claim 1, wherein said light source, said optical waveguide, said array of said plurality of quantum material chiplets, and said imaging array comprise a unitary device.

6. The sensor of claim 1, further comprising a baffle configured to reduce cross-talk between a first quantum material chiplet of said array of said plurality of quantum material chiplets and a second quantum material chiplet of said array of said plurality of quantum material chiplets.

7. The sensor of claim 1, wherein each quantum material chiplet is configured to emit the respective emission light having the respective emission wavelength λre based on the respective parameter value that comprises one value of a group of parameter values comprising a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each quantum material chiplet.

8. A system comprising:
a controller; and
a sensor,
wherein said sensor comprises:
a light source configured to generate input light having an input wavelength λᵢ;
an optical waveguide;
an array of a plurality of quantum material chiplets; and
an imaging array,
wherein said optical waveguide is configured to transmit the input light to said array of said plurality of quantum material chiplets,
wherein each quantum material chiplet is configured to absorb a portion of the input light from said optical waveguide and to emit a respective emission light having a respective emission wavelength λᵣₑ in response to the absorption of the portion of the input light and based on a respective parameter value at each quantum material chiplet, and
wherein said imaging array is configured to detect each respective emission light and output a detection signal based on the respective parameter value at each quantum material chiplet, and
wherein said controller comprises:
a memory having instructions stored therein; and
a processor configured to execute the instructions to cause said controller to:
cause the light source to generate the input light; and
determine each respective parameter value at each quantum material chiplet based on the detection signal.

9. The system of claim 8, wherein said light source comprises one of a group of light sources comprising a single tunable light source, an array of light emitting diodes, an array of vertical-cavity surface-emitting lasers, a grating antenna array operating over a frequency spectrum range, and combinations thereof.

10. The system of claim 8, further comprising:
a microwave emitter configured to emit microwave pulses to said array of said plurality of quantum material chiplets; and
an optical modulating element configured to modulate the input light.

11. The system of claim 10,
wherein said optical waveguide includes an optical modulation portion that includes said optical modulating element, and
wherein said optical modulating element comprises one of a group of optical modulating elements comprising a wavelength modulating element, a polarization modulating element, a mode modulating element, a nearfield phase modulating element, a gradient index lens, a diffractive element, a refractive element, a lenticular array, an intensity modulating element, and combinations thereof.

12. The system of claim 8, wherein said light source, said optical waveguide, said array of said plurality of quantum material chiplets, and said imaging array comprise a unitary device.

13. The system of claim 8, further comprising a baffle configured to reduce cross-talk between a first quantum material chiplet of said array of said plurality of quantum material chiplets and a second quantum material chiplet of said array of said plurality of quantum material chiplets.

14. The system of claim 8, wherein each quantum material chiplet is configured to emit the respective emission light having the respective emission wavelength λᵣₑ based on the respective parameter value that comprises one value of a group of parameter values comprising a magnetic field strength value, a magnetic field direction value, a change in magnetic field strength value, a change in magnetic field direction value, an electric field strength value, an electric field direction value, a change in electric field strength value, a change in electric field direction value, a strain value, a change in strain value, a temperature value, a change in temperature value, and combination thereof, at each quantum material chiplet.

15. A method of detecting a field of parameter values comprising:
causing, via a controller, a light source to generate input light having an input wavelength λᵢ,
transmitting, via an optical waveguide, the input light to an array of a plurality of quantum material chiplets, each of the plurality of quantum material chiplets is configured to absorb a portion of the input light from the optical waveguide and to emit a respective emission light having a respective emission wavelength λᵣₑ in response to the absorption of the portion of the input light and based on a respective parameter value at each quantum material chiplet;
detecting, via an imaging array, each respective emission light; and
outputting, via the imaging array, a detection signal based on the respective parameter value at each quantum material chiplet to obtain the field of parameter values of the array of the plurality of quantum material chiplets.

16. The method of claim 15, wherein said causing, via the controller, the light source to generate the input light comprises causing, via the controller, one of a group of light sources comprising a single tunable light source, an array of light emitting diodes, an array of vertical-cavity surface-emitting lasers, a grating antenna array operating over a frequency spectrum range, and combinations thereof, to generate the input light.

17. The method of claim 15, further comprising:
emitting, via a microwave emitter, microwave pulses to the array of the plurality of quantum material chiplets; and
modulating, via an optical modulating element, the input light.

18. The method of claim 17,
wherein the optical waveguide includes an optical modulation portion that includes the optical modulating element, and
wherein said modulating, via the optical modulating element, the input light comprises modulating via one of a group of optical modulating elements comprising a wavelength modulating element, a polarization modulating element, a mode modulating element, a nearfield phase modulating element, a gradient index lens, a diffractive element, a refractive element, a lenticular array, an intensity modulating element, and combinations thereof, the input light.

19. The method of claim 15, wherein said causing, transmitting, detecting, and outputting comprises causing the light source to generate the input light, transmitting the input light to the array of the plurality of quantum material chiplets, detecting each respective emission light, and outputting a detection signal via the light source, the optical waveguide, the array of the plurality of quantum material chiplets, and the imaging array comprising a unitary device.

20. The method of claim 15, further comprising reducing cross-talk, via a baffle, between a first quantum material chiplet of the array of the plurality of quantum material chiplets and a second quantum material chiplet of the array of the plurality of quantum material chiplets.
